(19) United States
(12) Patent Application Publication
(10) Pub. No.: US 2024/0105665 A1
(43) Pub. Date: Mar. 28, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Katsuyuki IMAI, Kawasaki Kanagawa (JP); Daisuke ANDO, Yokohama Kanagawa (JP); Toyokazu SHIBATA, Kawasaki Kanagawa (JP); Keiko KAJI, Akishima Tokyo (JP)

(21) Appl. No.: 18/116,680

(22) Filed: Mar. 2, 2023

(30) Foreign Application Priority Data
Sep. 22, 2022 (JP) 2022-151647

(51) Int. Cl. H01L 23/00

(52) U.S. Cl. CPC H01L 24/37; H01L 24/40; H01L 2224/4007; H01L 2224/40221

(57) ABSTRACT

According to one embodiment, a semiconductor device includes: a first frame, a second frame spaced apart from the first frame in a first direction, and a first joint terminal provided above a second chip provided on the second frame. The first frame includes a first terminal portion extending toward the second frame. The first joint terminal includes a second terminal portion extending toward the first frame. The second terminal portion includes a plane portion, a first projecting portion and a second projecting portion each branching out from the plane portion. An end portion of the first projecting portion and an end portion of the second projecting portion are respectively joined on the first terminal portion. The first projecting portion is different in a length in a first direction from the second projecting portion.

### CROSS-REFERENCE TO RELATED APPLICATIONS

This application is based upon and claims the benefit of priority from Japanese Patent Application No. 2022-151647, filed Sep. 22, 2022, the entire contents of which are incorporated herein by reference.

### FIELD

Embodiments described herein relate generally to a semiconductor device.

### BACKGROUND

A semiconductor device using a lead frame is known.

### BRIEF DESCRIPTION OF THE DRAWINGS

FIG. 1 is a plan view showing an example of a configuration of a semiconductor device according to an embodiment.

FIG. 2 is a plan view showing an example of an internal configuration of the semiconductor device according to the embodiment.

FIG. 3 is an enlarged view showing some of the internal configuration of the semiconductor device according to the embodiment.

FIG. 4 is a perspective view showing some of the internal configuration of the semiconductor device according to the embodiment.

FIG. 5 is a cross-sectional view showing an example of a configuration of the semiconductor device according to the embodiment.

FIG. 6 is a cross-sectional view showing a configuration of the semiconductor device according to the embodiment.

FIG. 7 is a diagram illustrating a flow of a formation process of a resin during its formation in the manufacturing process of the semiconductor device according to the embodiment.

FIG. 8 is a diagram illustrating a flow of the resin during its formation in the manufacturing process of the semiconductor device according to the embodiment.

### DETAILED DESCRIPTION

In general, according to one embodiment, a semiconductor device includes: a first frame; a first chip provided on the first frame; a second frame spaced apart from the first frame in a first direction; a second chip provided on the second frame; and a first joint terminal provided above the second chip and electrically coupled to the second chip, wherein the first frame includes a first terminal portion extending toward the second frame, the first joint terminal includes a second terminal portion extending toward the first frame, the second terminal portion includes a plane portion, a first branch portion, and a second branch portion, the first branch portion and the second branch portion each branching out from the plane portion, an end portion of the first branch portion and an end portion of the second branch portion are each joined on the first terminal portion, and the first branch portion is different in terms of a length in the first direction from the second branch portion.

Hereinafter, embodiments will be described with reference to the accompanying drawings. In the following description, constituent elements having substantially the same function and configuration will be assigned the same reference numeral or symbol and repetitive descriptions may be omitted. All of the descriptions of an embodiment are applicable as descriptions of another embodiment, unless explicitly or self-evidently excluded.

### 1. Embodiment

A semiconductor device according to an embodiment will be described. Hereinafter, a semiconductor device using a lead frame will be described as an example. The semiconductor device is used for, e.g., a transistor package.

### 1.1 Configuration of Semiconductor Device

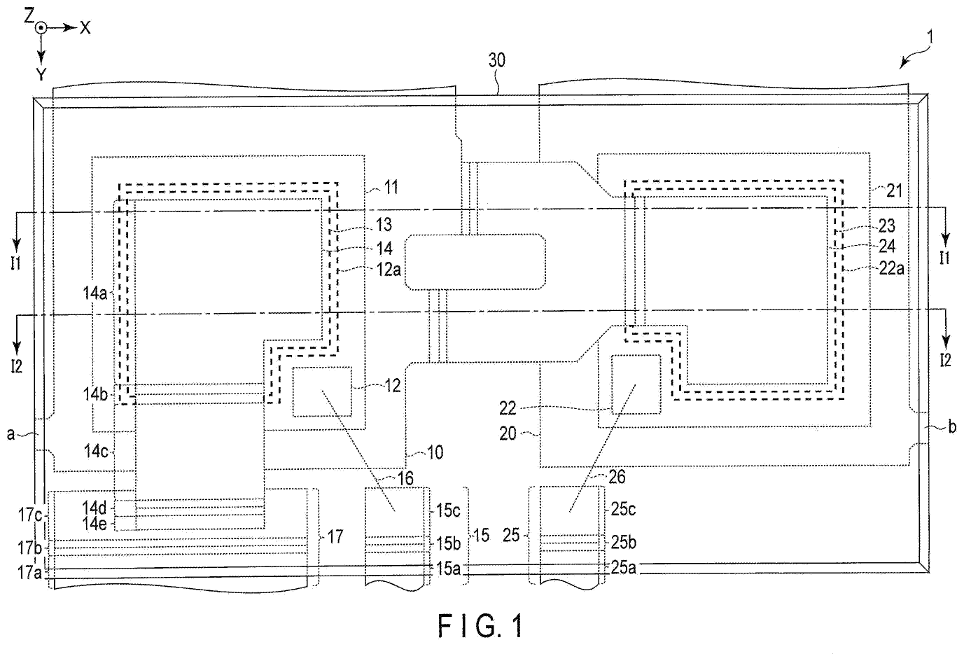

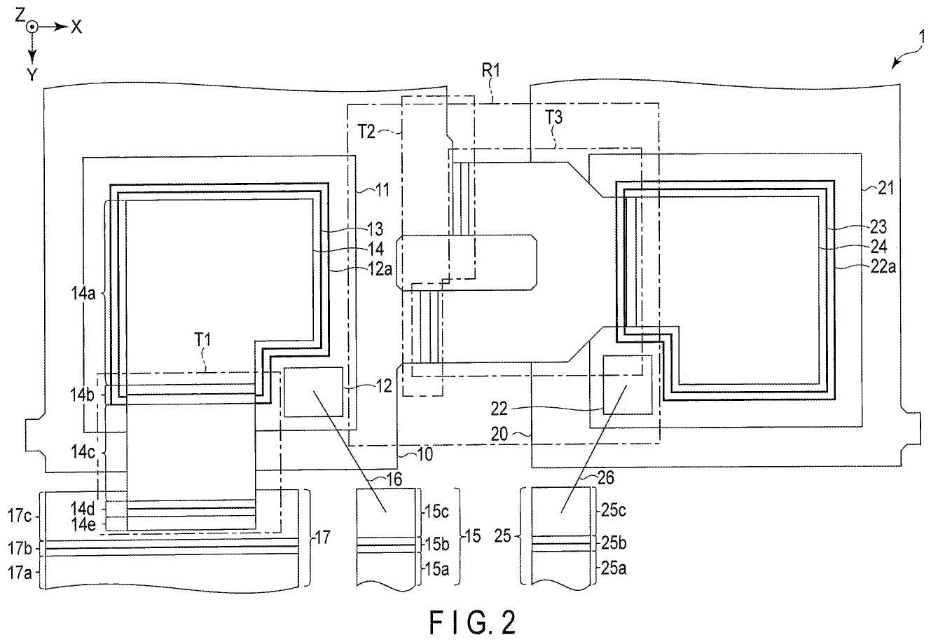

The configuration of the semiconductor device according to the present embodiment will be described with reference to FIG. 1 and FIG. 2. FIG. 1 is a plan view showing an example of the configuration of the semiconductor device according to the present embodiment. In the example shown in FIG. 1, a resin is indicated by the solid line. The internal constituent elements covered with the resin are indicated by the broken line. The outside of the resin (a part not covered with the resin) is indicated by the solid line. FIG. 2 is a plan view showing an example of the internal configuration of the semiconductor device according to the embodiment. The example shown in FIG. 2 omits the resin.

As shown in FIG. 1, a semiconductor device 1 includes a lead frame 10, a chip 11, an electrode 12, an electrode 12a, a joint member 13, a joint terminal 14, an electrode terminal 15, an interconnect 16, an electrode terminal 17, a lead frame 20, a chip 21, an electrode 22, an electrode 22a, a joint member 23, a joint terminal 24, an electrode terminal 25, an interconnect 26, and a resin 30. In the following description, an X direction is substantially parallel to a surface of the lead frame 10 and corresponds to, for example, a direction from the lead frame 10 to the lead frame 20 (the direction from the electrode terminal 17 to the electrode terminal 15). A Y direction is substantially parallel to the surface of the lead frame 10 and corresponds to, for example, a direction from the lead frame 10 to the electrode terminal 17. A Z direction is substantially perpendicular to the surface of the lead frame 10 and corresponds to a direction from the lead frame 10 to the chip 11.

The resin 30 is, for example, an epoxy resin. Part of the lead frame 10, all of the chip 11, all of the electrode 12, all of the electrode 12a, all of the joint member 13, all of the joint terminal 14, part of the electrode terminal 15, all of the interconnect 16, part of the electrode terminal 17, part of the lead frame 20, all of the chip 21, all of the electrode 22, all of the electrode 22a, all of the joint member 23, all of the joint terminal 24, part of the electrode terminal 25, and all of the interconnect 26 are covered with the resin 30.

As shown in FIG. 2, the lead frame 10 is a frame configured to support and fix the chip 11. The lead frame 10 is formed into, for example, a plate shape. One end portion of the lead frame 10, which is far from the electrode terminal 17, extends in the Y direction. The lead frame 10 is formed of a conductive material and may be, for example, a metal material. The lead frame 10 will be described later in detail.

The chip 11 is, for example, an integrated circuit (IC) chip. The chip 11 is provided on the lead frame 10.

The electrode 12 is, for example, a gate electrode. The electrode 12 is provided on the chip 11. The electrode 12 is formed of a conductive material and may be, for example, a metal material. The electrode 12 may include, for example, a joint terminal.

The electrode 12a is, for example, a source electrode. The electrode 12a is formed into, for example, a substantially letter L shape when viewed from a top (when viewed from the top of the drawing sheet of FIG. 2). The electrode 12a is provided on the chip 11. The electrode 12a is formed of a conductive material and may be, for example, a metal material. Furthermore, a drain electrode made of a conductive material serving as a metal member is provided on an upper side or rear side of the chip 11.

The joint member 13 is, for example, a solder joint. The joint member 13 is formed into, for example, a substantially letter L shape when viewed from the top. The joint member 13 is provided on the electrode 12a. The joint member 13 electrically couples the electrode 12a to the joint terminal 14.

The joint terminal 14 electrically couples, for example, the electrode 12a to the electrode terminal 17. The joint terminal 14 is formed into, for example, a substantially letter L shape when viewed from the top. The joint terminal 14 is provided on the joint member 13. The joint terminal 14 is electrically coupled to the chip 11 with the joint member 13 and the electrode 12a intervening therebetween. The joint terminal 14 is formed of a conductive material and may be, for example, a metal material. The joint terminal 14 will be described later in detail.

The electrode terminal 15 is, for example, a gate terminal. The electrode terminal 15 is spaced apart from the lead frame 10 in the Y direction. One end portion of the electrode terminal 15, which is far from the lead frame 10, extends in the Y direction. The electrode terminal 15 is formed of a conductive material and may be, for example, a metal material.

The electrode terminal 15 includes a base portion 15a, a bending portion 15b, and a joint portion 15c. For example, the electrode terminal 15 is bent upward on the boundary between the base portion 15a and the bending portion 15b, and is bent in the Y direction on the boundary between the bending portion 15b and the joint portion 15c. The surface of the base portion 15a and the surface of the joint portion 15c are substantially parallel to each other. The surface of the joint portion 15c is positioned above the surface of the base portion 15a. In other words, the electrode terminal 15 has a step in the Y direction.

The interconnect 16 is, for example, a bonding wire. One end of the interconnect 16 is joined to the electrode 12. The other end of the interconnect 16 is joined to the joint portion 15c of the electrode terminal 15. The interconnect 16 electrically couples the electrode 12 to the electrode terminal 15. The interconnect 16 is formed of a conductive material and may be, for example, a metal material. In the case of the electrode 12 having a joint terminal, the joint terminal of the electrode 12, instead of the interconnect 16, may be electrically coupled to the electrode terminal 15.

The electrode terminal 17 is, for example, a source terminal. The electrode terminal 17 is spaced apart from the electrode terminal 15 in the X direction. The electrode terminal 17 is spaced apart from the lead frame 10 in the Y direction. One end portion of the electrode terminal 17, which is far from the lead frame 10, extends in the Y direction. The electrode terminal 17 is formed of a conductive material and may be, for example, a metal material.

The electrode terminal 17 includes a base portion 17a, a bending portion 17b, and a joint portion 17c. For example, the electrode terminal 17 is bent upward on the boundary between the base portion 17a and the bending portion 17b, and is bent in the Y direction on the boundary between the bending portion 17b and the joint portion 17c. The surface of the base portion 17a and the surface of the joint portion 17c are substantially parallel to each other. The surface of the joint portion 17c is positioned above the surface of the base portion 17a. In other words, the electrode terminal 17 has a step in the Y direction.

The lead frame 20 is a frame configured to support and fix the chip 21. The lead frame 20 is formed into, for example, a plate shape. The lead frame 20 is spaced apart from the lead frame 10 in the X direction. One end portion of the lead frame 20, which is far from the electrode terminal 25, extends in the Y direction. The lead frame 20 is formed of a conductive material and may be, for example, a metal material.

The chip 21 is, for example, an IC chip. The chip 21 is provided on the lead frame 20.

The electrode 22 is, for example, a gate electrode. The electrode 22 is provided on the chip 21. The electrode 22 is formed of a conductive material and may be, for example, a metal material. The electrode 22 may include, for example, a joint terminal.

The electrode 22a is, for example, a source electrode. The electrode 22a is formed into, for example, a substantially letter L shape when viewed from the top. The electrode 22a is provided on the chip 21. The electrode 22a is formed of a conductive material and may be, for example, a metal material. Furthermore, a drain electrode made of a conductive material serving as a metal member is provided on the upper side or rear side of the chip 21.

The joint member 23 is, for example, a solder joint. The joint member 23 is formed into, for example, a substantially letter L shape when viewed from the top. The joint member 23 is provided on the electrode 22a. The joint member 23 electrically couples the electrode 22a to the joint terminal 24.

The joint terminal 24 electrically couples, for example, the electrode 22a to the lead frame 10. The joint terminal 24 is formed into, for example, a substantially letter L shape when viewed from the top. The joint terminal 24 is provided on the joint member 23. The joint terminal 24 is electrically coupled to the chip 21 with the joint member 23 and the electrode 22a intervening therebetween. The joint terminal 24 is formed of a conductive material and may be, for example, a metal material. The joint terminal 24 will be described later in detail.

The electrode terminal 25 is, for example, a gate terminal. The electrode terminal 25 is spaced apart from the electrode terminal 15 in the X direction. The electrode terminal 25 is spaced apart from the lead frame 20 in the Y direction. One end portion of the electrode terminal 25, which is far from the lead frame 20, extends in the Y direction. The electrode terminal 25 is formed of a conductive material and may be, for example, a metal material.

The electrode terminal 25 includes a base portion 25a, a bending portion 25b, and a joint portion 25c. For example, the electrode terminal 25 is bent upward on the boundary between the base portion 25a and the bending portion 25b, and is bent in the Y direction on the boundary between the bending portion 25b and the joint portion 25c. The surface of the base portion 25a and the surface of the joint portion 25c are substantially parallel to each other. The surface of the joint portion 25c is positioned above the surface of the base portion 25a. In other words, the electrode terminal 25 has a step in the Y direction.

The interconnect 26 is, for example, a bonding wire. One end of the interconnect 26 is joined to the electrode 22. The other end of the interconnect 26 is joined to the joint portion 25c of the electrode terminal 25. The interconnect 26 electrically couples the electrode 22 to the electrode terminal 25. The interconnect 26 is formed of a conductive material and may be, for example, a metal material. In the case of the electrode 22 having a joint terminal, the joint terminal of the electrode 22, instead of the interconnect 26, may be electrically coupled to the electrode terminal 25.

The joint terminal 14 will be described in detail with reference to FIG. 2.

As shown in FIG. 2, the joint terminal 14 includes a base portion 14a and a terminal portion T1. The terminal portion T1 is provided on one of the end portions of the joint terminal 14, which is closer to the electrode terminal 17. The terminal portion T1 is formed into, for example, a substantially rectangular shape when viewed from the top. The terminal portion T1 includes a bending portion 14b, a bridge portion 14c, a bending portion 14d, and a joint portion 14e.

For example, the joint terminal 14 is bent upward on the boundary between the base portion 14a and the bending portion 14b, and is bent in the Y direction on the boundary between the bending portion 14b and the bridge portion 14c. For example, the joint terminal 14 is bent downward on the boundary between the bridge portion 14c and the bending portion 14d, and is bent in the Y direction on the boundary between the bending portion 14d and the joint portion 14e. The surface of the base portion 14a, the surface of the bridge portion 14c, and the surface of the joint portion 14e are substantially parallel to each other. The surface of the bridge portion 14c is positioned above the surface of the base portion 14a and the surface of the joint portion 14e. In other words, the joint terminal 14 has a step in the Y direction.

As shown in FIG. 2, the terminal portion T1 is provided on the electrode terminal 17. More specifically, the joint portion 14e of the joint terminal 14 is joined on the joint portion 17c of the electrode terminal 17. This electrically couples the terminal portion T1 to the electrode terminal 17. In other words, the joint terminal 14 is electrically coupled to the electrode terminal 17 with the terminal portion T1 intervening therebetween.

In a housing of the semiconductor device 1, an injection port for a resin (reference symbol “a” in FIG. 1) is provided on an end portion which is close to the lead frame 10 and is located in the vicinity of the electrode terminal 17. A vent (reference symbol “b” in FIG. 1) is provided at a position aligned next to the injection port in the X direction, on the other end portion which is far from the injection port and is close to the lead frame 20 in the housing of the semiconductor device 1.

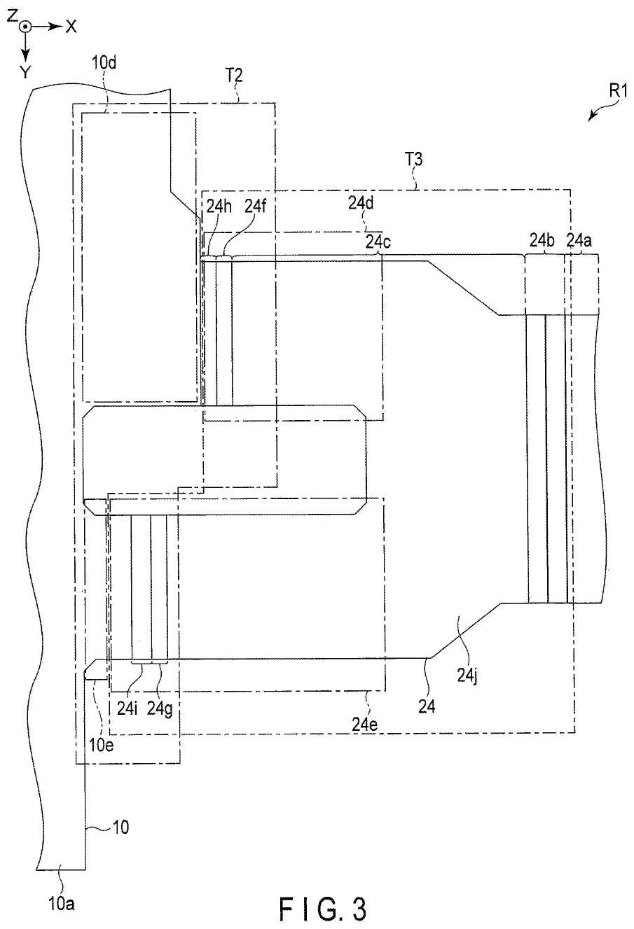

The lead frame 10 will be described in detail with reference to FIG. 3. FIG. 3 is an enlarged view showing some of the internal configuration of the semiconductor device 1 according to the embodiment (the enlarged view of the region R1 in FIG. 2). The example shown in FIG. 3 omits the chips 11 and 21, the electrodes 22 and 22a, and the joint member 23.

As shown in FIG. 3, the lead frame 10 includes a terminal portion T2. The terminal portion T2 is positioned on one of the end portions of the lead frame 10, which is close to the joint terminal 24 (close to the lead frame 20). The terminal portion T2 extends toward the joint terminal 24. The terminal portion T2 is formed into, for example, a substantially letter U shape when viewed from the top.

However, in the terminal portion T2, a part which is relatively close to the injection port for the resin (also referred to as a “resin injection port”) in the lower part of the drawing sheet of FIG. 3 is smaller in a length in the X direction than a part which is relatively distant from the resin injection port in the upper part of the drawing sheet of FIG. 3.

That is, in the terminal portion T2, one end portion close to the lead frame 20 at a part relatively close to a part connecting the aforementioned resin injection port to the vent in the lower part of the drawing sheet of FIG. 3 is positioned closer to the resin injection port as compared to the other end portion close to the lead frame 20 at a part relatively distant from a part connecting the resin injection port to the vent in the upper part of the drawing sheet of FIG. 3.

The terminal portion T2 includes projecting portions 10d and 10e each of which branches out from the base portion 10a and projects toward the joint terminal 24 (toward the lead frame 20). In other words, one end portion of the terminal portion T2, which is close to the joint terminal 24, is divided into two parts. The projecting portion 10d and the projecting portion 10e branch out in the Y direction and each extend in the X direction.

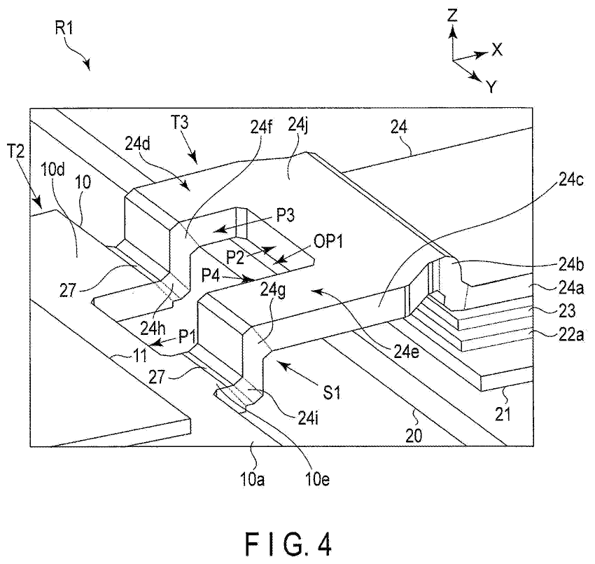

The projecting portion 10d is provided at a position which is on the upside of the drawing sheet of FIG. 3 and is more distant from a part connecting the resin injection port to the vent as compared to the projecting portion 10e. The projecting portion 10e is provided at a position, as shown in the lower part of the drawing sheet of FIG. 4, closer to the part connecting the resin injection port to the vent as compared to the projecting portion 10d. However, in the terminal portion T2, the projecting portion 10e is smaller in a length in the X direction than the projecting portion 10d.

That is, in the terminal portion T2, one end portion which is close to the lead frame 20 and is provided on the projecting portion 10e is positioned closer to the resin injection port as compared to the other end portion which is close to the lead frame 20 and is provided on the projecting portion 10d.

The joint terminal 24 will be described in detail with reference to FIG. 3.

As shown in FIG. 3, the joint terminal 24 includes a base portion 24a and a terminal portion T3. The terminal portion T3 is positioned on one end portion of the joint terminal 24, which is close to the lead frame 10. The terminal portion T3 extends toward the lead frame 10. The terminal portion T3 is formed into, for example, a substantially letter Y shape when viewed from the top.

However, in the terminal portion T3, a part which is relatively close to the resin injection port in the lower part of the drawing sheet of FIG. 3 is greater in a length in the X direction than a part which is relatively distant from the resin injection port in the upper part of the drawing sheet of FIG. 3.

The terminal portion T3 includes a bending portion 24b, a bridge portion 24c, bending portions 24f and 24g, and joint portions 24h and 24i.

The bending portion 24f and the joint portion 24h of the terminal portion T3 are provided at a position, as shown in the upper part of the drawing sheet of FIG. 3, more distant from a part connecting the resin injection port to the vent as compared to the bending portion 24g and the joint portion 24i.

Furthermore, the bending portion 24g and the joint portion 24i of the terminal portion T3 are provided at a position of the terminal portion T3, as shown in the lower part of the drawing sheet of FIG. 3, closer to the part connecting the injection port to the vent as compared to the bending portion 24f and the joint portion 24h.

That is, in the terminal portion T3, one end portion which is close to the lead frame 10 and is provided on the projecting portion 24e (second branch portion) is positioned closer to the resin injection port as compared to the other end portion which is close to the lead frame 10 and is provided on the projecting portion 24d (first branch portion).

For example, the joint terminal 24 is bent upward on the boundary between the base portion 24a and the bending portion 24b, and is bent in the X direction on the boundary between the bending portion 24b and the bridge portion 24c. For example, the joint terminal 24 is bent downward on the boundary between the bridge portion 24c and the bending portion 24f, and is bent in the X direction on the boundary between the bending portion 24f and the joint portion 24h. For example, the joint terminal 24 is bent downward on the boundary between the bridge portion 24c and the bending portion 24g, and is bent in the X direction on the boundary between the bending portion 24g and the joint portion 24i. The surface of the base portion 24a and the surface of the bridge portion 24c are substantially parallel to each other. The surface of the bridge portion 24c is positioned above the surface of the base portion 24a, the surface of the joint portion 24h, and the surface of the joint portion 24i. In other words, the joint terminal 24 has a step in the X direction.

The terminal portion T3 includes projecting portions 24d and 24e each of which projects toward the lead frame 10. In other words, one end portion of the terminal portion T3, which is close to the lead frame 10, is divided into two parts. The projecting portions 24d and 24e are spaced apart from each other in the Y direction.

In other words, the terminal portion T3 includes a plane portion 24j, with the projecting portion 24d (first branch portion) and the projecting portion 24e (second branch portion) each branching out from the plane portion 24j. The projecting portion 24d and the projecting portion 24e branch out in the Y direction and each extend in the X direction.

The projecting portion 24d is provided at a position, as shown in the upper part of the drawing sheet of FIG. 3, more distant from a part connecting the resin injection port to the vent as compared to the projecting portion 24e. The projecting portion 24e is provided at a position, as shown in the lower part of the drawing sheet of FIG. 3, closer to the part connecting the resin injection port to the vent as compared to the projecting portion 24d. However, in the terminal portion T3, the projecting portion 24e is greater in a length in the X direction than the projecting portion 24d.

The projecting portion 24d includes part of the bridge portion 24c, all of the bending portion 24f, and all of the joint portion 24h. The projecting portion 24e includes part of the bridge portion 24c, all of the bending portion 24g, and all of the joint portion 24i.

As shown in FIG. 3, the end portion of the terminal portion T3 is provided on the terminal portion T2. More specifically, the joint portion 24h of the terminal portion T3 is joined on the projecting portion 10d of the terminal portion T2. The joint portion 24i of the terminal portion T3 is joined on the projecting portion 10e of the terminal portion T2. In other words, the end portion of the projecting portion 24d of the terminal portion T3 is joined on the projecting portion 10d of the terminal portion T2. The end portion of the projecting portion 24e of the terminal portion T3 is joined on the projecting portion 10e of the terminal portion T2. That is, the terminal portion T3 and the terminal portion T2 are joined together via two joint surfaces. Hereinafter, a combination of the end portion of the terminal portion T2 in contact with the joint surfaces, and the end portion of the terminal portion T3 in contact with the joint surfaces will be referred to as a “joint part”. This electrically couples the terminal portion T3 to the terminal portion T2. In other words, the joint terminal 24 is electrically coupled to the lead frame 10 with the terminal portions T3 and T2 intervening therebetween.

The lead frame 10, the electrode terminals 15 and 17, the lead frame 20, and the electrode terminal 25 shown in FIG. 2 correspond to some portions of a lead frame (not shown), which remain after cut or removal of the lead frame (not shown) through a processing process.

FIG. 4 is a perspective view showing some of the internal configuration of the semiconductor device 1 according to the present embodiment (the perspective view of the region R1 in FIG. 2). The example shown in FIG. 4 omits the electrode 22.

As shown in FIG. 4, the end portion of the projecting portion 24d is joined to the end portion of the projecting portion 10d. The end portion of the projecting portion 24d is joined to the projecting portion 10d via the joint member 27 formed on the end portion of the projecting portion 10d. The joint member 27 is, for example, a solder joint. The joint member 27 electrically couples the terminal portion T2 to the terminal portion T3. As shown in FIG. 4, the end portion of the projecting portion 24e is provided on the end portion of the projecting portion 10e. The end portion of the projecting portion 24e is joined to the projecting portion 10e via a joint member 27 formed on the end portion of the projecting portion 10e.

An end surface of the terminal portion T3 (the surface of the terminal portion T3, the surface being sandwiched between the projecting portions 24d and 24e and facing the lead frame 10 (to be also referred to as a “surface P2”)) is positioned closer to the lead frame 20 as compared to an end surface of the terminal portion T2 (the surface of the terminal portion T2, the surface being sandwiched between the projecting portions 10d and 10e and facing the lead frame 20 (to be also referred to as a “surface P1”)).

With the above structure, an upper part of a space (hereinafter, also referred to as a “space S1”) surrounded by the terminal portion T2, the joint member 27, the terminal portion T3, the joint member 23, the electrode 22a, the chip 21, and the lead frame 20 is not blocked by the terminal portions T2 and T3. While the projecting portion 24d has a surface which faces the projecting portion 24e and is referred to as a “surface P3” and the projecting portion 24e has a surface which faces the projecting portion 24d and is referred to as a “surface P4”, the semiconductor device 1 has a region surrounded by the surfaces P1, P2, P3, and P4. In other words, the terminal portions T2 and T3 (the projecting portions 10d, 10e, 24d, and 24e) form an opening (hereinafter, also referred to as an “opening OP1”). That is, the semiconductor device 1 has the opening OP1 formed by the terminal portions T2 and T3. A region surrounded by the surfaces P1, P2, P3, and P4 corresponds to the opening OP1. Both ends in the Y direction of the space S1 are not blocked.

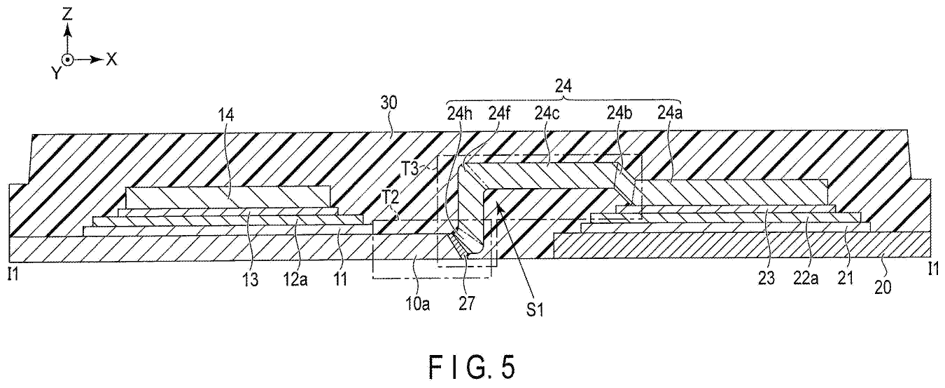

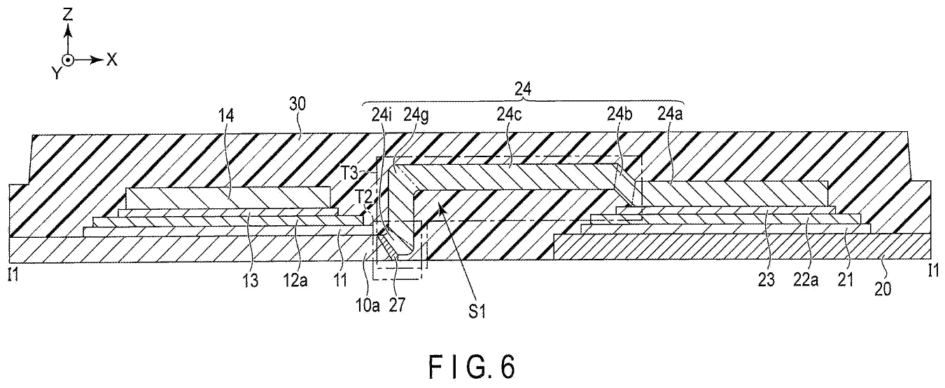

A cross-sectional structure of the semiconductor device 1 will be described with reference to FIG. 5 and FIG. 6. FIG. 5 is a cross-sectional view (the cross-sectional view taken along the line I1-I1 in FIG. 1) showing an example of a structure of the semiconductor device 1 according to the embodiment. FIG. 6 is a cross-sectional view (the cross-sectional view taken along the line I2-I2 in FIG. 1) showing an example of a structure of the semiconductor device 1 according to the embodiment.

As shown in FIG. 5, the chip 11 is provided on the lead frame 10. The electrode 12a is provided on the chip 11. The joint member 13 is provided on the electrode 12a. The joint terminal 14 is provided on the joint member 13.

The chip 21 is provided on the lead frame 20. The electrode 22a is provided on the chip 21. The joint member 23 is provided on the electrode 22a. The joint terminal 24 is provided on the joint member 23. The bending portions 24b and 24f enable the joint terminal 24 to be bent in such a manner that the surface of the bridge portion 24c is positioned above the surface of the base portion 10a.

The joint portion 24h is joined to the base portion 10a via the joint member 27.

The lead frame 10, the chip 11, the electrode 12a, the joint member 13, the joint terminal 14, the lead frame 20, the chip 21, the electrode 22a, the joint member 23, and the joint terminal 24 are covered with the resin 30. The space S1 is filled with the resin 30.

As shown in FIG. 6, the chip 11 is provided on the lead frame 10. The electrode 12a is provided on the chip 11. The joint member 13 is provided on the electrode 12a. The joint terminal 14 is provided on the joint member 13.

The chip 21 is provided on the lead frame 20. The electrode 22a is provided on the chip 21. The joint member 23 is provided on the electrode 22a. The joint terminal 24 is provided on the joint member 23. The bending portions 24b and 24g enable the joint terminal 24 to be bent in such a manner that the surface of the bridge portion 24c is positioned above the surface of the base portion 10a.

The joint portion 24i is joined to the base portion 10a via the joint member 27.

### 1.2 Method of Manufacturing Semiconductor Device

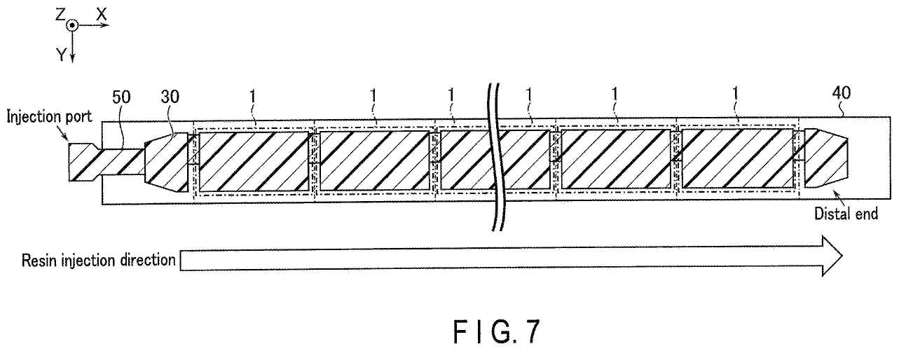

A method of manufacturing the semiconductor device 1 will be described. In the present embodiment, a plurality of semiconductor devices 1 are formed using a single lead frame. Before the formation of the resin 30, internal constituent elements (hereinafter, also referred to as “constituent element groups”) of the semiconductor device 1 shown in FIG. 2 are arranged in a matrix pattern on the single lead frame. These constituent element groups are sealed with the resin 30. Hereinafter, a formation process of the resin 30 will be described with reference to FIG. 7. FIG. 7 is a diagram illustrating a formation process of the resin 30. The example in FIG. 7 shows a method (the transfer method) of forming the resin 30 using a mold 50 with respect to a plurality of constituent element groups provided in a row in the X direction on the lead frame 40.

As shown in FIG. 7, the resin 30 is injected from an injection port of the mold 50. The resin 30 flows in the X direction (the direction from the left side of the drawing sheet of FIG. 7 toward the right side of the drawing sheet of FIG. 7) from the injection port of the mold 50 to the distal end of the mold 50. By this, the plurality of constituent element groups provided on the lead frame 40 are sealed with the resin 30 between the injection port of the mold 50 and the distal end of the mold 50.

After the formation of the resin 30, the lead frame 40 is cut and removed, thereby resulting in the formation of the plurality of semiconductor devices 1.

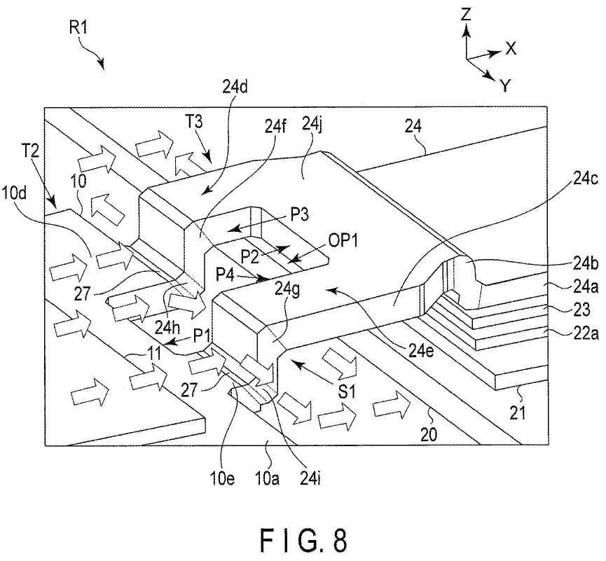

A flow of the resin 30 during its formation will be described with reference to FIG. 8. FIG. 8 is a diagram illustrating a flow of the resin 30. In the example shown in FIG. 8, a flow of the resin 30 being injected in order to cover the constituent element groups of the semiconductor device 1 shown in FIG. 2 and heading to the space S1 is indicated by an arrow.

As shown in FIG. 8, the resin 30 is injected from the X direction side (the side close to the lead frame 10). The resin 30 travels by detouring along the outside of the projecting portion 24d to flow into the space S1. The resin 30 travels by detouring along the outside of the projecting portion 24e to flow into the space S1. The resin 30 travels downward through the opening OP1 formed by the terminal portions T2 and T3, and flows into the space S1.

The configuration according to the present embodiment can improve the yield of the semiconductor device.

In the present embodiment, the terminal portion T2 includes the projecting portions 10d and 10e projecting toward the joint terminal 24. The projecting portion 10d and the projecting portion 10e are spaced apart from each other in the Y direction. The terminal portion T3 includes projecting portions 24d and 24e each of which projects toward the lead frame 10. The projecting portion 24d and the projecting portion 24e are spaced apart from each other in the Y direction.

With a configuration in which the terminal portions T2 and T3 extend in the direction in which the resin 30 is injected and the end portion of the terminal portion T3 is joined on the terminal portion T2, the resin 30 travels by detouring along the outside of the terminal portion T3 to flow into the space S1. However, the terminal portions T2 and T3 extending in the direction in which the resin 30 is injected may obstruct the flow of the resin 30, thereby causing a void in the space S1 or resulting in the space S1 not being filled with the resin 30.

On the other hand, in the present embodiment, the end portion of the projecting portion 24d of the terminal portion T3 is provided on the projecting portion 10d of the terminal portion T2. The end portion of the projecting portion 24e of the terminal portion T3 is provided on the projecting portion 10e of the terminal portion T2. The surface P2 of the terminal portion T3, which is sandwiched between the projecting portions 24d and 24e and faces the lead frame 10, is positioned closer to the lead frame 20 as compared to the surface P1 of the terminal portion T2, which is sandwiched between the projecting portions 10d and 10e and faces the lead frame 20. In other words, the semiconductor device 1 has the opening OP1 formed by the terminal portions T2 and T3. Accordingly, during the formation process of the resin 30, the resin 30 not only travels by detouring along the outside of the projecting portions 24d and 24e to flow into the space S1 but also travels downward through the opening OP1 to flow into the space S1. This can improve the filling property of the resin 30. This enables a resin whose curing time is relatively short to be used as the resin 30, for example.

A difference in elongation due to heat between the terminal portion T2 and the resin 30 becomes larger as an area of the resin 30 covering the terminal portion T2 (the area of the resin 30 in contact with the terminal portion T2) increases. Therefore, depending on the area of the resin 30 covering the terminal portion T2, peeling between the terminal portion T2 and the resin 30 may occur due to heat. With respect to the terminal portion T3, similarly, depending on the area of the resin 30 covering the terminal portion T3 (the area of the resin 30 in contact with the terminal portion T3), peeling between the terminal portion T3 and the resin 30 may occur due to heat.

On the other hand, in the present embodiment, the semiconductor device 1 has the opening OP1 formed by the terminal portions T2 and T3. Accordingly, the area of the resin 30 covering the terminal portion T2 is smaller than the area of the resin 30 that covers the terminal portion T2 in the case of the semiconductor device 1 having no opening. Accordingly, a difference in elongation due to heat between the terminal portion T2 and the resin 30 becomes smaller as compared to such a difference in the case of the semiconductor device 1 having no opening. The area of the resin 30 covering the terminal portion T3 is smaller than the area of the resin 30 that covers the terminal portion T3 in the case of the semiconductor device 1 having no opening. Accordingly, a difference in elongation due to heat between the terminal portion T3 and the resin 30 becomes smaller as compared to such a difference in the case of the semiconductor device 1 having no opening. This can suppress peeling between the terminal portion T2 and the resin 30 and peeling between the terminal portion T3 and the resin 30.

Herein, suppose the semiconductor device 1 has a configuration in which in the terminal portion T2 of the lead frame 10 described above, one end portion which is close to the lead frame 20 and is provided on the projecting portion 10d and the other end portion which is close to the lead frame 20 and is provided on the projecting portion 10e are aligned in position in a direction intersecting a direction from the resin injection port to the vent.

Suppose that in this configuration, in the terminal portion T3 of the lead frame 20, one end portion which is close to the lead frame 10 and is provided on the projecting portion 24d and the other end portion which is close to the lead frame 10 and is provided on the projecting portion 10e are aligned in position in the direction intersecting the direction from the resin injection port to the vent.

Such a configuration undesirably causes merging of resin at the rear sides of the terminal portions T2 and T3 in the space S1, thereby involving a risk of insufficient strength or poor appearance due to a defect called a weld line.

On the other hand, in the present embodiment, in the terminal portion T2 of the lead frame 10, one end portion which is close to the lead frame 20 and is provided on the projecting portion 10e is positioned closer to the resin injection port as compared to the other end portion which is close to the lead frame 20 and is provided on the projecting portion 10d more distant from the injection port as compared to the projecting portion 10e.

Furthermore, in the present embodiment, in the terminal portion T3 of the lead frame 20, one end portion which is close to the lead frame 10 and is provided on the projecting portion 24e positioned closer to the injection port as compared to the projecting portion 24d is positioned closer to the resin injection port as compared to the other end portion which is close to the lead frame 10 and is provided on the projecting portion 24d.

In other words, the projecting portion 10d projects further toward the lead frame 20 than the projecting portion 10e and is greater in a length in the X direction than the projecting portion 10e.

In this case, the projecting portion (first branch portion) 24d is smaller in a length in the X direction than the projecting portion (second branch portion) 24e.

In this case, the projecting portion 24e is positioned closer to the electrode (gate electrode) 12 as compared to the projecting portion 24d. In other words, the projecting portion 24d is different in a length in the X direction from the projecting portion 24e.

This can improve the flowability of resin flowing between two branches of the terminal portion T2 and between two branches of the terminal portion T3, and as a result, prevents merging of resin from occurring at the rear sides of the terminal portions T2 and T3 in the space S1.

Furthermore, the configuration described above, in which of the plurality of projecting portions, an end portion relatively close to the injection port is positioned closer to the injection port can further improve the flowability of resin flowing between two branches of the terminal portion T2 and two branches of the terminal portion T3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first frame;
a first chip provided on the first frame;
a second frame spaced apart from the first frame in a first direction;
a second chip provided on the second frame; and
a first joint terminal provided above the second chip and electrically coupled to the second chip,
wherein the first frame includes a first terminal portion extending toward the second frame,
the first joint terminal includes a second terminal portion extending toward the first frame,
the second terminal portion includes a plane portion, a first branch portion, and a second branch portion, the first branch portion and the second branch portion each branching out from the plane portion,
an end portion of the first branch portion and an end portion of the second branch portion are each joined on the first terminal portion, and
the first branch portion is different in terms of a length in the first direction from the second branch portion.

2. The semiconductor device according to claim 1, wherein a first surface of the second terminal portion, the first surface being sandwiched between the first branch portion and the second branch portion and facing the first frame, is positioned closer to the second frame as compared to a second surface of the first terminal portion, the second surface facing the second frame.

3. The semiconductor device according to claim 2, further comprising a region surrounded by the first surface of the second terminal portion, the second surface of the first terminal portion, a third surface of the first branch portion, the third surface facing the second branch portion, and a fourth surface of the second branch portion, the fourth surface facing the first branch portion.

4. The semiconductor device according to claim 2, wherein the first terminal portion includes a third branch portion and a fourth branch portion each of which projects toward the second frame and which are spaced apart from each other in a second direction intersecting the first direction,
the end portion of the first branch portion is joined on the third branch portion,
the end portion of the second branch portion is joined on the fourth branch portion, and
the second surface of the first terminal portion is sandwiched between the third branch portion and the fourth branch portion.

5. The semiconductor device according to claim 1, further comprising a gate electrode,
wherein the second branch portion is positioned closer to the gate electrode as compared to the first branch portion, and
the second branch portion is greater in terms of the length in the first direction than the first branch portion.

6. The semiconductor device according to claim 1, wherein the first terminal portion includes a third branch portion and a fourth branch portion each of which branches toward the second frame,
an end portion of the second terminal portion is joined on the third branch portion and the fourth branch portion, and
the third branch portion is different in terms of a length in the first direction from the fourth branch portion.

7. The semiconductor device according to claim 6, further comprising a gate electrode,
wherein the fourth branch portion is positioned closer to the gate electrode as compared to the third branch portion, and
the fourth branch portion is smaller in terms of a length in the first direction than the third branch portion.
